(19) United States
(12) Patent Application Publication
(10) Pub. No.: US 2026/0304672 A1
(43) Pub. Date: Oct. 1, 2026

(54) WIRELESS POWER SOURCE DEVICE

(71) Applicants: Andreas KERASSIDIS, Peronnes-lez-Binche (BE); Stavros KERASIDIS, Peronnes-lez-Binche (BE)

(72) Inventor: Stavros KERASIDIS, Peronnes-lez-Binche (BE)

(73) Assignees: Andreas KERASSIDIS, Peronnes-lez-Binche (BE); Stavros KERASIDIS, Peronnes-lez-Binche (BE)

(21) Appl. No.: 19/479,193

(22) PCT Filed: May 2, 2024
(86) PCT No.: PCT/EP2024/062160

§ 371 Date: Oct. 27, 2025

(30) Foreign Application Priority Data
May 4, 2023 (BE) 2023/0026

(51) Int. Cl. H05K 7/14; H02M 7/00; H05K 7/20

(52) U.S. Cl. CPC H05K 7/1432; H02M 7/003; H05K 7/2089

(57) ABSTRACT

A wireless power supply device that comprises an adapter configured to receive a tool battery and a converter configured to receive said adapter, wherein said converter comprises a power outlet, at least one USB-A port, at least one USB-C port, an on/off button, an LED button, an attachment strap provided with a ring, a ventilator, and a transformer.

### FIELD OF THE INVENTION

The present disclosure relates to wireless power supply devices, and in particular to wireless power supply devices for the conversion of branded tool batteries.

### BACKGROUND OF THE INVENTION

Wireless power supply devices are already in existence.

However, these devices are not easily transportable, cannot power different types of appliances, or are not usable on existing batteries.

There is consequently a need for an improved device.

### SUMMARY OF THE INVENTION

To this end, a wireless power supply device is proposed that comprises an adapter configured to receive a tool battery and a converter configured to receive said adapter, wherein said converter comprises a power outlet, at least one USB-A port, at least one USB-C port, an on/off button, an LED button, an attachment strap provided with a ring, a ventilation means, and a transformer.

Said adapter may preferably be integrated in the converter.

Said adapter preferably comprises a button for locking to/unlocking from said converter when said adapter is not integrated in said converter.

Said converter is preferably made up of a casing provided with opposing fascia panels attached to one another by attachment means.

Said ventilation means is preferably a 12V DC ventilation means and said transformer is a 12V-18V-230V transformer.

Said at least one USB-A port, at least one USB-C port, on/off button, and LED button are mounted on a printed circuit board.

Said power outlet is preferably of type E/F.

Said converter is preferably configured to receive said adapter by way of complementary attachment means of said adapter and of said tool battery, and respective complementary notches of said adapter and of said converter allow power from said battery to flow to said converter via said adapter.

Said adapter is preferably configured to receive the tool battery by way of complementary attachment means of said adapter and of said tool battery.

Said attachment strap is preferably a red strip 25 millimeters in width made of polypropylene, said ring is a 25 millimeter D ring of stainless steel, and the stud inside said converter casing allowing the strap to be hung up may be 3 millimeters in diameter, 40 millimeters in length, and made of stainless steel.

The fascia panels of the converter casing, said adapter, and said button for locking/unlocking said battery adapter are made by plastics injection molding.

### BRIEF DESCRIPTION OF THE FIGURES

Non-limiting examples will be described with reference to the following figures:

FIG. 1 shows the embodiment of the wireless power supply device according to the invention.

FIG. 2 shows an exploded view of the embodiment of the wireless power supply device according to the invention.

### DETAILED DESCRIPTION

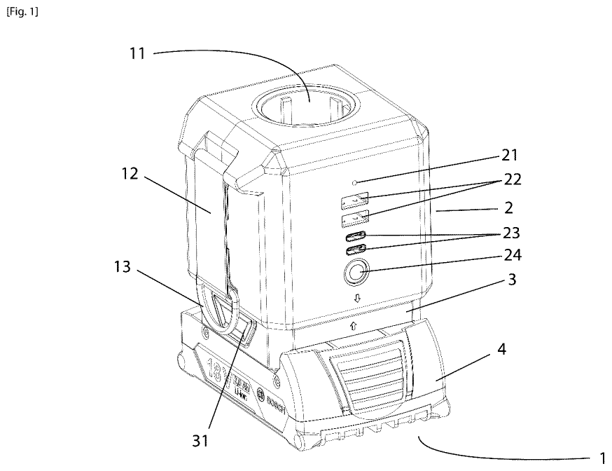

FIG. 1 shows the embodiment of the wireless power supply device according to the invention.

FIG. 1 shows a wireless power supply device 1 that comprises an adapter 3 configured to receive a tool battery 4 and a converter 2 configured to receive said adapter 3, wherein said converter 2 comprises a power outlet 11, at least one USB-A port 22, at least one USB-C port 23, an on/off button 24, an LED button 21, an attachment strap 12 provided with a ring 13, and a ventilation means, and said adapter 3 comprises a button 31 for locking to/unlocking from said converter 2.

The adapter will thus make it possible to use different brands of tool batteries 4. An adapter may be specific to a tool battery, for example the Bosch brand “Power For All” battery makes it possible to power the brand's gardening and DIY tools.

The adapter can be integrated in the converter and form a single physical object including both of these functions.

Accordingly, since the device now comprises just one object, the quantity of materials required to manufacture it is reduced.

The power outlet 11 may be of type E/F, a round outlet comprising two cylindrical orifices 5 millimeters in diameter with center-to-center spacing of 19 millimeters. This is a grounded outlet. Such an outlet can handle a voltage of 230V (volts) and a power of 150 watts.

The power outlet thus makes it possible to power appliances with limited energy requirements, for example desk lamps, radios, or small refrigerators.

A USB-A (Universal Serial Bus) or USB-C port is available on portable appliances, for example laptops and cell phones, and tablets. The availability of such ports on the converter thus make it possible to charge or recharge these appliances for rapid charging via a USB cable, ensuring greater charging efficiency than using mains power.

The on/off button indicates whether the converter is operational.

Thus, if there is no appliance connected to the device, the device can be switched off.

Conversely, the device must be switched on in order to power an appliance connected thereto.

The LED button indicates the power level available in the device. If the LED button is off, it is probable that the battery from which the energy is converted has run out of power. Accordingly, the converter has no more energy to convert.

The attachment strap provided with a ring 13 allows the device to be hung up on a support, for example a nail in a wall.

The attachment strap may be a red strip 25 millimeters in width made of polypropylene.

The ring may be a 25 millimeter D ring of stainless steel. The stud inside the converter casing allowing the strap to be hung up may likewise be 3 millimeters in diameter, 40 millimeters in length, and made of stainless steel.

The converter may be cubic in shape, the cube having a side length of 80 millimeters.

The adapter may be 70 millimeters in width. Once connected to the converter, the adapter foot can be 20 millimeters in height.

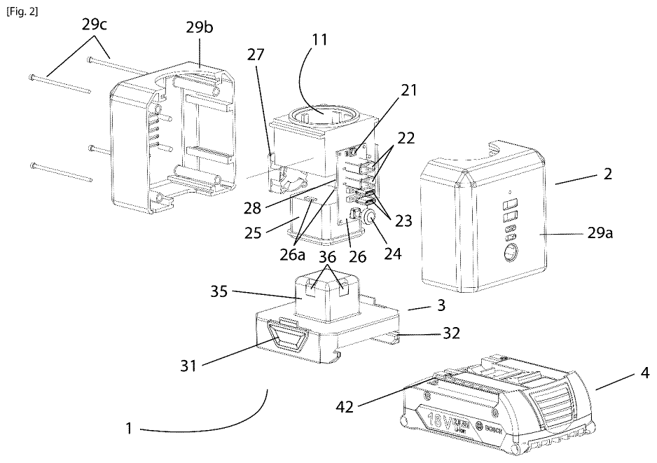

The ventilation means is not visible in this figure and will be described in FIG. 2.

The locking/unlocking button 31 makes it possible to secure the adapter in the converter once the adapter has been positioned in the converter.

In the event of the adapter being integrated in the converter, there is then no need for a locking/unlocking button.

The button 31 for locking to/unlocking from the battery adapter is made by plastics injection molding.

FIG. 2 shows an exploded view of the embodiment of the tool battery conversion device according to the invention.

As described in FIG. 1, the wireless power supply device 1 comprises an adapter 3 configured to receive a tool battery 4 and a converter 2 configured to receive said adapter 3, wherein said converter 2 comprises a power outlet 11, at least one USB-A port 22, at least one USB-C port 23, an on/off button 24, an LED button 21, and said adapter 3 comprises a button 31 for locking to/unlocking from said converter 2.

FIG. 2 shows said converter 2 made up of a casing provided with two opposing fascia panels 29a, 29b attached to one another by attachment means 29c.

For example, the attachment means 29c are M3×50 millimeter M3 hexagon socket screws.

Said converter 2 comprises a 12V DC ventilation means 27, a 12V-18V-230V transformer 28, and a contact piece 25 in contact with the adapter 3.

By circulating air, the 12V DC (direct current) 25 millimeter ventilation means makes it possible to maintain a constant, stable temperature within the converter during operation, so extending its service life.

The 12V-18V-230V transformer 28 makes it possible to convert the voltage of the tool battery 4 into a voltage usable by the power outlet 11 or the USB ports 22, 23. For example, said transformer converts the 18V voltage of the tool battery 4 into a 230V voltage for powering a 230V appliance on the type E/F power outlet 11.

A printed circuit board 26 allows the USB-A port 22, the USB-C port 23, the on/off button 24, and the LED button 21 to be mounted.

The fascia panels 29a, 29b of the converter casing together with the adapter are made by way of plastics injection molding.

The fascia panel 29b facing the ventilation means 27 comprises a grille allowing the air in the converter to be exhausted to the outside.

Said converter 2 is configured to receive said adapter 3 by way of complementary attachment means 35 of said adapter 3 and 25 of said tool battery 4. Respective complementary notches 36 of said adapter 3 and 26a of said converter 2 allow power from said battery to flow to said converter via said adapter.

Said converter 3 is configured to receive the tool battery 4 by way of complementary attachment means 32 of said adapter 3 and 42 of said tool battery 4.

For example, said complementary attachment means make it possible to position said battery under the adapter by lateral sliding.

The advantage of the invention is that of permitting easier transport of a wireless power supply for various types of common appliances from an existing tool battery. Use of the device according to the invention thus makes it possible to avoid the use of extension power cords.

1. A wireless power supply device comprising:
an adapter configured to receive a tool battery; and
a converter configured to receive said adapter,
wherein said converter comprises a power outlet socket, at least one USB-A output port, at least one USB-C output port, an on/off button, an LED button, and a ventilator,
wherein the converter is configured to receive the adapter and further comprises an attachment strap provided with a ring configured to hang up the wireless power supply device on a support, and a transformer configured to convert voltage of the tool battery into a voltage usable by the power output socket, the at least one USB-A output port and the at least one USB-C output port.

2. The device according to claim 1, wherein said adapter is integrated in the converter.

3. The device according to claim 1, said adapter comprises a button for locking to/unlocking from said converter when said adapter is not integrated in said converter.

4. The device according to claim 1, wherein said converter is made up of a casing provided with two opposing fascia panels attached to one another by connectors.

5. The device according to claim 1, wherein said ventilator is a 12V DC ventilator.

6. The device according to claim 1, wherein said at least one USB-A output port, at least one USB-C output port, on/off button, and LED button are mounted on a printed circuit board.

7. The device according to claim 1, wherein said power output socket is of type E/F.

8. The device according to claim 1, wherein said converter is configured to receive said adapter by way of a complementary connector of said adapter and of said tool battery, and respective complementary notches of said adapter, and of said converter allow power from said battery to flow to said converter via said adapter.

9. The device according to claim 1, wherein said adapter is configured to receive the tool battery by way of complementary recess of said adapter and of said tool battery.

10. The device according to claim 3, wherein said attachment strap is a red strip 25 millimeters in width made of polypropylene, said ring is a 25 millimeter D ring of stainless steel, and the stud inside said converter casing allowing the strap to be hung up is 3 millimeters in diameter, 40 millimeters in length, and made of stainless steel.
